(19) United States
(12) Patent Application Publication
(10) Pub. No.: US 2018/0011399 A1
(43) Pub. Date: Jan. 11, 2018

(54) Process for Reducing the Defects in an Ordered Film of Block Copolymer

(71) Applicant: Arkema France, Colombes (FR)

(72) Inventors: Xavier Chevalier, Grenoble (FR); Raber Inoubli, Pau (FR); Christophe Navarro, Bayonne (FR); Celia Nicolet, Sauvagnon (FR)

(73) Assignee: Arkema France, Colombes (FR)

(21) Appl. No.: 15/545,113

(22) PCT Filed: Jan. 21, 2016
(86) PCT No.: PCT/FR2016/050115

§ 371 Date: Jul. 20, 2017

(30) Foreign Application Priority Data
Jan. 21, 2015 (FR) 15 50470

(51) Int. Cl. G03F 1/72; C08G 81/02

(52) U.S. Cl. CPC G03F 1/72; C08G 81/021

(57) ABSTRACT

The present invention relates to a process for reducing the number of defects in an ordered film comprising a block copolymer (BCP). The invention also relates to the compositions used to obtain these ordered films and to the resulting ordered films that can be used in particular as masks in the lithography field.

The present invention relates to a process for reducing the number of defects in an ordered film comprising a block copolymer (BCP). The invention also relates to the compositions used to obtain these ordered films and to the resulting ordered films that can be used in particular as masks in the lithography field.

The process which is the subject of the invention is particularly useful when it is a question of obtaining ordered films with a large surface area which exhibit a reduction in the number of defects compared with what is observed when a single block copolymer is used for the same period.

The term “period” is intended to mean the mean minimum distance separating two neighbouring domains having the same chemical composition, separated by a domain having a different chemical composition.

The use of block copolymers to generate lithography masks is now well known. While this technology is promising, difficulties remain in generating large surface areas of masks that can be industrially exploited. Processes for manufacturing masks for lithography which have sizeable surface areas with a minimum of defects or at least a level of defects which is acceptable for lithographic applications in particular are sought.

The nanostructuring of a block copolymer of a surface treated by the process of the invention can take the forms such as cylindrical (hexagonal symmetry (primitive hexagonal lattice symmetry “6 mm”) according to the Hermann-Mauguin notation, or tetragonal symmetry (primitive tetragonal lattice symmetry “4 mm”)), spherical (hexagonal symmetry (primitive hexagonal lattice symmetry “6 mm” or “6/mmm”), or tetragonal symmetry (primitive tetragonal lattice symmetry “4 mm”), or cubic symmetry (lattice symmetry m⅓m), lamellar or gyroidal. Preferably, the preferred form which the nanostructuring takes is of the hexagonal cylindrical type.

The process for the self-assembling of block copolymers on a surface treated according to the invention is governed by thermodynamic laws. When the self-assembling results in a morphology of cylindrical type, each cylinder is surrounded by 6 equidistant neighbouring cylinders if there is no defect. Several types of defects can thus be identified. The first type is based on the evaluation of the number of neighbours around a cylinder which constitutes the arrangement of the block copolymer, also known as coordination number defects. If five or seven cylinders surround the cylinder under consideration, a coordination number defect will be regarded as being present. The second type of defect considers the mean distance between the cylinders surrounding the cylinder under consideration [W. Li, F. Qiu, Y. Yang and A. C. Shi, Macromolecules, 43, 2644 (2010); K. Aissou, T. Baron, M. Kogelschatz and A. Pascale, Macromol., 40, 5054 (2007); R. A. Segalman, H. Yokoyama and E. J. Kramer, Adv. Matter., 13, 1152 (2003); R. A. Segalman, H. Yokoyama and E. J. Kramer, Adv. Matter., 13, 1152 (2003)]. When this distance between two neighbours is greater than two % of the mean distance between two neighbours, a defect will be regarded as being present. In order to determine these two types of defects, use is conventionally made of the associated Voronoï constructions and Delaunay triangulations. After binarization of the image, the centre of each cylinder is identified. The Delaunay triangulation subsequently makes it possible to identify the number of first-order neighbours and to calculate the mean distance between two neighbours. It is thus possible to determine the number of defects.

This counting method is described in the paper by Tiron et al. (J. Vac. Sci. Technol. B 29(6), 1071-1023, 2011).

A final type of defect relates to the angle of cylinders of the block copolymer which is deposited on the surface. When the block copolymer is no longer perpendicular to the surface but lying down parallel to the latter, a defect of orientation will be regarded as having appeared.

The process of the invention makes it possible to attain nanostructured assemblies in the form of ordered films with a reduction in the number of defects in terms of orientations, of coordination numbers or of distances over large monocrystalline surfaces.

Few studies refer to technologies aimed at obtaining ordered films of block copolymers deposited on a surface exhibiting a considerable reduction in the number of defects with a view to manufacturing masks for lithography applications.

U.S. Pat. No. 8,513,356 discloses a composition comprising at least one ordered polystyrene-b-poly(methyl methacrylate) diblock, with a PS volume fraction of between 0.65 and 0.87, satisfying an arrangement equation at 225° C., and a non-ordered polystyrene-b-poly(methyl methacrylate) diblock, with a PS volume fraction of between 0.50 and 0.99 satisfying a non-arrangement equation at 225° C.

The compositions exhibit an improvement in the degree of perpendicularity of the cylinders. The possibility of reducing for example the coordination-number or distance defects is in no way mentioned.

Shin & al. in J. Mater. Chem, 2010, 20, 7241 mention an improvement in the self-organization of ordered films of BCP with a large period via a mixture of BCP consisting of BCPs of the cylindrical type, without however giving precise measurements of this improvement, and without taking into account the fact that the composition of the mixture is not the same as that of the initial cylindrical polymer. It is therefore very difficult to decorrelate the effect of the variation in composition from the effect of the addition of a non-ordered-BCP and from that of the effect of the variation in period on the improvement in the self-organization.

Pure BCPs which organize themselves in ordered films with few defects are very difficult to obtain for ordered films of large surface area. Mixtures comprising at least one BCP are one solution to this problem, and it is shown in the present invention that, in the case where it is sought to reduce the number of defects for BCPs exhibiting ordered morphologies, mixtures comprising at least one BCP having an order-disorder temperature (TODT), combined with at least one compound not having a TODT, are a solution when the order-disorder transition temperature (TODT) of the mixture is lower than the TODT of the BCP alone. In the case of these mixtures, a decrease in the defects on the ordered films obtained using these mixtures is noted compared with the ordered films obtained with a block copolymer alone.

### SUMMARY OF THE INVENTION

The invention relates to a process for reducing the number of defects of an ordered film of block copolymer, said ordered film comprising a mixture of at least one block copolymer having an order-disorder transition temperature (TODT) and at least one Tg with at least one compound not having a TODT, this mixture having a TODT below the TODT of the block copolymer alone, the process comprising the following steps:
mixing at least one block copolymer having a TODT and at least one compound not having a TODT, in a solvent,
depositing this mixture on a surface,
curing the mixture deposited on the surface at a temperature between the highest Tg of the block copolymer and the TODT of the mixture.

### DETAILED DESCRIPTION

As regards the block copolymer(s) having an order-disorder transition temperature, any block copolymer, regardless of its associated morphology, may be used in the context of the invention, whether it is a diblock, linear or star triblock or linear, comb or star multiblock copolymer.

Preferably, diblock or triblock copolymers and more preferably diblock copolymers are involved.

The order-disorder transition temperature TODT, which corresponds to a phase separation of the constituent blocks of the block copolymer, can be measured in various ways, such as DSC (differential scanning calorimetry), SAXS (small angle X-ray scattering), static birefringence, dynamic mechanical analysis, DMA, or any other method which makes it possible to visualize the temperature at which phase separation occurs (corresponding to the order-disorder transition). A combination of these techniques may also be used.

Mention may be made, in a non-limiting manner, of the following references referring to TODT measurement:
N. P. Balsara et al, Macromolecules 1992, 25, 3896-3901.
N. Sakamoto et al, Macromolecules 1997, 30, 5321-5330 and Macromolecule 1997, 30, 1621-1632
J. K. Kim et al, Macromolecules 1998, 31, 4045-4048.

The preferred method used in the present invention is DMA.

It will be possible, in the context of the invention, to mix n block copolymers with m compounds, n being an integer between 1 and 10, limits included. Preferably, n is between 1 and 5, limits included, and preferably n is between 1 and 2, limits included, and more preferably n is equal to 1, m being an integer between 1 and 10, limits included. Preferably, m is between 1 and 5, limits included, and preferably m is between 1 and 4, limits included, and more preferably m is equal to 1.

These block copolymers may be synthesized by any technique known to those skilled in the art, among which may be mentioned polycondensation, ring opening polymerization or anionic, cationic or radical polymerization, it being possible for these techniques to be controlled or uncontrolled, and optionally combined with one another. When the copolymers are prepared by radical polymerization, the latter can be controlled by any known technique, such as NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”) or ITP (“Iodine Transfer Polymerization”).

According to one preferred form of the invention, the block copolymers are prepared by controlled radical polymerization, more particularly still by nitroxide mediated polymerization, the nitroxide being in particular N-(tert-butyl)-1-diethylphosphono-2,2-dimethylpropyl nitroxide.

According to a second preferred form of the invention, the block copolymers are prepared by anionic polymerization.

When the polymerization is carried out in radical fashion, the constituent monomers of the block copolymers will be chosen from the following monomers: at least one vinyl, vinylidene, diene, olefinic, allyl or (meth)acrylic monomer. This monomer is more particularly chosen from vinylaromatic monomers, such as styrene or substituted styrenes, in particular α-methylstyrene, silylated styrenes, acrylic monomers, such as acrylic acid or its salts, alkyl, cycloalkyl or aryl acrylates, such as methyl, ethyl, butyl, ethylhexyl or phenyl acrylate, hydroxyalkyl acrylates, such as 2-hydroxyethyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, methacrylic monomers, such as methacrylic acid or its salts, alkyl, cycloalkyl, alkenyl or aryl methacrylates, such as methyl (MMA), lauryl, cyclohexyl, allyl, phenyl or naphthyl methacrylate, hydroxyalkyl methacrylates, such as 2-hydroxyethyl methacrylate or 2-hydroxypropyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloylpropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl) ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, diene monomers, including butadiene or isoprene, as well as fluoroolefinic monomers and vinylidene monomers, among which may be mentioned vinylidene fluoride, alone or as a mixture of at least two abovementioned monomers.

When the polymerization is carried out anionically, the monomers will be chosen, in a non-limiting manner, from the following monomers:

at least one vinyl, vinylidene, diene, olefinic, allyl or (meth)acrylic monomer. These monomers are more particularly chosen from vinylaromatic monomers, such as styrene or substituted styrenes, in particular α-methylstyrene, acrylic monomers, such as alkyl, cycloalkyl or aryl acrylates, such as methyl, ethyl, butyl, ethylhexyl or phenyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, alkyl, cycloalkyl, alkenyl or aryl methacrylates, such as methyl (MMA), lauryl, cyclohexyl, allyl, phenyl or naphthyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloylpropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl) ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, diene monomers, including butadiene or isoprene, as well as fluoroolefinic monomers and vinylidene monomers, among which may be mentioned vinylidene fluoride, alone or as a mixture of at least two abovementioned monomers.

Preferably, the block copolymers having an order-disorder transition temperature consist of a block copolymer, one of the blocks of which comprises a styrene monomer and the other block of which comprises a methacrylic monomer; more preferably, the block copolymers consist of a block copolymer, one of the blocks of which comprises styrene and the other block of which comprises methyl methacrylate.

The compounds not having an order-disorder transition temperature will be chosen from block copolymers, as defined above, but also random copolymers, homopolymers and gradient copolymers. According to one preferred variant, the compounds are homopolymers or random copolymers and have a monomer composition identical to that of one of the blocks of the block copolymer having a TODT.

According to a more preferred form, the homopolymers or random copolymers comprise styrene monomers or methacrylic monomers. According to a further preferred form, the homopolymers or random copolymers comprise styrene or methyl methacrylate.

The compounds not having an order-disorder transition temperature will also be chosen from plasticizers, among which mention may be made, in a non-limiting manner, of branched or linear phthalates, such as di-n-octyl, dibutyl, 2-ethylhexyl, diethylhexyl, diisononyl, diisodecyl, benzylbutyl, diethyl, dicyclohexyl, dimethyl, linear diundecyl and linear ditridecyl phthalates, chlorinated paraffins, branched or linear trimellitates, in particular diethylhexyl trimellitate, aliphatic esters or polymeric esters, epoxides, adipates, citrates and benzoates.

The compounds not having an order-disorder transition temperature will also be chosen from fillers, among which mention may be made of inorganic fillers, such as carbon black, carbon nanotubes or non-carbon nanotubes, fibres, which may or may not be milled, stabilizers (light stabilizers, in particular UV stabilizers, and heat stabilizers), dyes, and photosensitive inorganic or organic pigments, for instance porphyrins, photoinitiators, i.e. compounds capable of generating radicals under irradiation.

The compounds not having an order-disorder transition temperature will also be chosen from polymeric or non-polymeric ionic compounds.

A combination of the compounds mentioned may also be used in the context of the invention, such as a block copolymer not having a TODT and a random copolymer or homopolymer not having a TODT. It will be possible, for example, to mix a block copolymer having a TODT, a block copolymer not having a TODT and a filler, a homopolymer or a random copolymer for example not having a TODT.

The invention therefore also relates to the compositions comprising at least one block copolymer having a TODT and at least one compound, this or these compound(s) not having a TODT.

The TODT of the mixture which is the subject of the invention will have to be below the TODT of the organized block copolymer alone, but will have to be above the glass transition temperature, Tg, measured by DSC (differential scanning calorimetry), of the block having the highest Tg.

In terms of morphological behaviour of the mixture during self-assembly, this means that the composition comprising a block copolymer having an order-disorder transition temperature and at least one compound not having an order-disorder transition temperature will exhibit self-assembly at a temperature lower than that of the block copolymer alone.

The ordered films obtained in accordance with the invention exhibit a reduction in the number of defects compared with ordered films obtained with one or more block copolymers having TODTs.

The curing temperatures enabling self-assembly will be between the glass transition temperature, Tg, measured by DSC (differential scanning calorimetry), of the block having the highest Tg and the TODT of the mixture, preferably between 1 and 50° C. below the TODT of the mixture, preferably between 10 and 30° C. below the TODT of the mixture, and more preferably between 10 and 20° C. below the TODT of the mixture.

The process of the invention allows an ordered film to be deposited on a surface such as silicon, the silicon exhibiting a native or thermal oxide layer, germanium, platinum, tungsten, gold, titanium nitrides, graphenes, BARC (Bottom Anti-Reflective Coating) or any other anti-reflective layer used in lithography. Sometimes, it may be necessary to prepare the surface. Among the known possibilities, a random copolymer, the monomers of which may be totally or partly identical to those used in the composition of block copolymer and/or of the compound which it is desired to deposit, is deposited on the surface. In a pioneering article, Mansky et al. (Science, vol 275 pages 1458-1460, 1997) clearly describes this technology, which is now well known to those skilled in the art.

According to one variant of the invention, the surfaces can be said to be “free” (flat and homogeneous surface, both from a topographical and from a chemical viewpoint) or can exhibit structures for guidance of the block copolymer “pattern”, whether this guidance is of the chemical guidance type (known as “guidance by chemical epitaxy”) or physical/topographical guidance type (known as “guidance by graphoepitaxy”).

In order to manufacture the ordered film, a solution of the block copolymer composition is deposited on the surface and then the solvent is evaporated according to techniques known to those skilled in the art, such as, for example, the spin coating, doctor blade, knife system or slot die system technique, but any other technique can be used, such as dry deposition, that is to say deposition without involving a predissolution.

A heat treatment or treatment by solvent vapour, a combination of the two treatments, or any other treatment known to those skilled in the art which allows the block copolymer composition to become correctly organized while becoming nanostructured, and thus to establish the ordered film, is subsequently carried out. In the preferred context of the invention, the curing is carried out thermally at a temperature that is higher than TODT of block copolymer that exhibit a TODT.

The nanostructuring of a mixture of block copolymer having a TODT and of a compound deposited on a surface treated by means of the process of the invention can take the forms such as cylindrical (hexagonal symmetry (primitive hexagonal lattice symmetry “6 mm”)) according to the Hermann-Mauguin notation, or tetragonal symmetry (primitive tetragonal lattice symmetry “4 mm”)), spherical (hexagonal symmetry (primitive hexagonal lattice symmetry “6 mm” or “6/mmm”)), or tetragonal symmetry (primitive tetragonal lattice symmetry “4 mm”), or cubic symmetry (lattice symmetry m⅓m)), lamellar or gyroidal. Preferably, the preferred form which the nanostructuring takes is of the hexagonal cylindrical type.

### Example 1: Order-Desorder Transition Temperature Analysis by Dynamical Mechanical Analysis

Two different molecular weight block copolymers PS-b-PMMA are synthesized by conventially anionic process or commercially available product can be used.

Characterizations of the products are in Table 1.

TABLE 1
Characterizations of PS-b-PMMA

| | Characterizations | | | | | |
|---|---|---|---|---|---|---|
| Product | Mp PS | Mp PMMA | Mp copo | Disper- | % m | % m |
| name | (kg/mol) | (kg/mol) | (kg/mol) | sity | PS | PMMA |
| Copoly- | 23.6 | 11.8 | 35.4 | 1.07 | 66.6 | 33.4 |
| mer 1 | | | | | | |
| Copoly- | 63.2 | 29.0 | 92.2 | 1.09 | 68.5 | 31.5 |
| mer 2 | | | | | | |

These two polymers are analyzed in the same conditions by dynamical mechanical analysis (DMA). DMA enables the measure of the storage modulus G′ and loss modulus G″ of the material and to determine the phase tan Δ defined as G″/G′.

Measurements are realized on an ARES viscoelastimeter, on which a 25 mm-PLAN geometry is set. The air gap is set at 100° C. and, once the sample settled in the geometry at 100° C., a normal force is applied to make sure of the contact between the sample and the geometry. A sweep in temperature is realized at 1 Hz. A 0.1% initial deformation is applied to the sample. It is then automatically adjusted to stay above the sensitivity limit of the probe (0.2 cm·g).

The temperature is set in step mode from 100 to 260° C., measurement is taken every 2° C. with an equilibration time of 30 s.

For both polymers, some transitions are observed: after the glass transition (Tg) characterized by a first maximum of tan Δ, the polymer reaches elastomeric plateau (G′ is higher than G″). In the case of a block copolymer that self-assembles, the block copolymer is structured on the elastomeric plateau.

After elastomeric plateau of Copolymer 1, G′ becomes lower than G″ which shows that the copolymer is not structured anymore. Order-disorder transition is reached and T_{odt} is defined as the first crossing between G′ and G″.

In the case of Copolymer 2, T_{odt} is not observed as G′ is always higher than G″. This block copolymer does not show any T_{odt} lower than its degradation temperature.

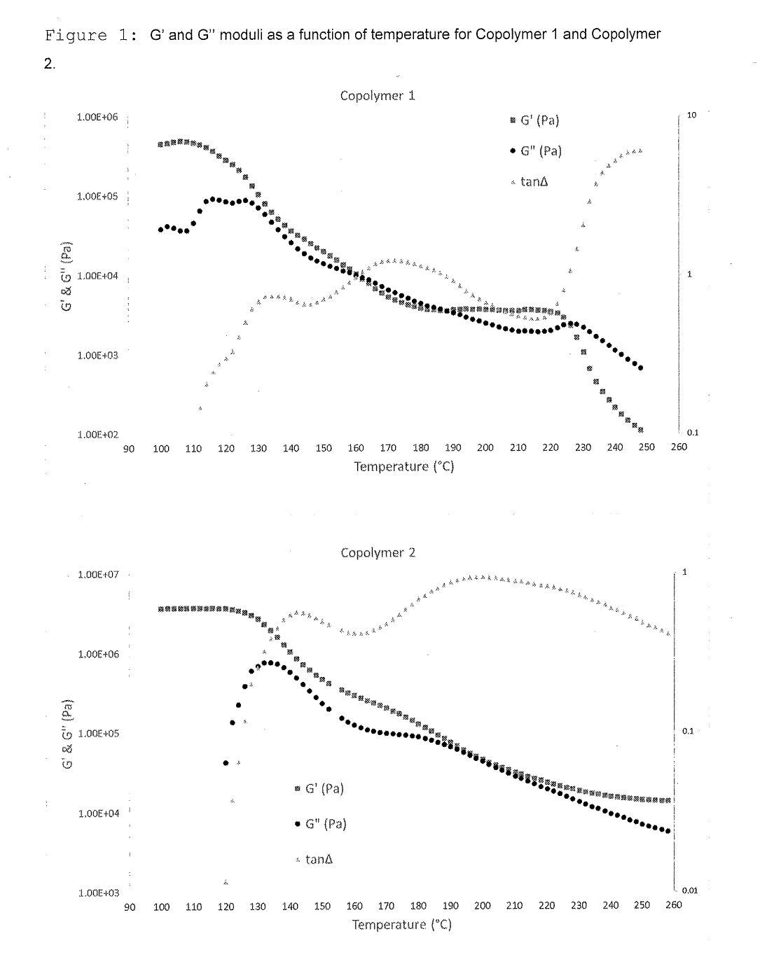

AMD results are in Table 2 and the associated graphs in FIG. 1.

TABLE 2
T_{odt} of different block copolymers PS-b-PMMA

| | T_{odt} |
|---|---|
| Copolymer 1 | 161 |
| Copolymer 2 | — |

### Example 2

### Thicknesses and Defectivity for Direct Self-Assembly of Block Copolymers:

2.5×2.5 cm silicon substrate were used after appropriate cleaning according to known art as for example piranha solution then washed with distilled water.

Then a solution of a random PS-r-PMMA as described for example in WO2013083919 (2% in propylene glycol monomethylic ether acetate, PGMEA) or commercially available from Polymer source and as appropriate composition known from the art to be of appropriate energy for the block copolymer to be then self-assembled is deposit on the surface of the silicon substrate by spin coating. Other technic for this deposition can also be used. The targeted thickness of the film was 70 nm. Then annealing was carried out at 220° C. for 10 minutes in order to graft a monolayer of the copolymer on the surface. Excess of non-grafted copolymer was removed by PGMEA rinse.

Then a solution of bloc-copolymer (s) in solution (1% PGMEA) was deposit over the silicon treated substrate by spin coating to a obtained a targeted thickness. The film was then annealed for example at 230° C. for 5 min in so the bloc-copolymer(s) can self-assemble. Depending on the analysis to be performed (scanning electron microscopy, atomic force microscopy) contrast of the nanostructure could be enhanced by a treatment using acetic acid followed by distilled water rinse, or soft oxygen plasma, or combination of both treatment.

Three different molecular weight block copolymers PS-b-PMMA were synthesized by conventially anionic process or commercially available product could be used.

Characterizations of the products are in Table 3

| Block | Mp PS | Mp PMMA | Mp copo | Disper- | % m | % m | TODT | Period |
|---|---|---|---|---|---|---|---|---|
| copolymer | (kg/mol) ^{a} | (kg/mol) ^{a} | (kg/mol) ^{a} | sity | PS ^{b} | PMMA ^{b} | (° C.) ^{c} | (nm) |
| Copolymer 3 | 59.9 | 26.4 | 86.3 | 1.11 | 69.4 | 30.6 | — | ~48 nm |
| Copolymer 4 | 67.4 | 31.1 | 98.5 | 1.18 | 68.4 | 31.6 | — | ~54 nm |
| Copolymer 5 | 23.6 | 10.6 | 34.2 | 1.09 | 69.0 | 31.0 | ~160 | ~24 nm |

^{a} As determined by SEC (sized exclusion chromatography, polystyren standards)
^{b} Détermined par NMR ¹H
^{c} Détermined par DMA (dynamical mechanical analysis as described in example 1). TODT for copolymer 3 and 4 doesn't not exist.

Copolymers 4 and 5 were then blended (dry blending or solution blending) with a weight ratio of 80/20, ie 80% copolymer 4 and copolymer 3 was tested as comparative for the reference. Aim is to obtained the same period with blended copolymers 4 and 5 as for copolymer 3.

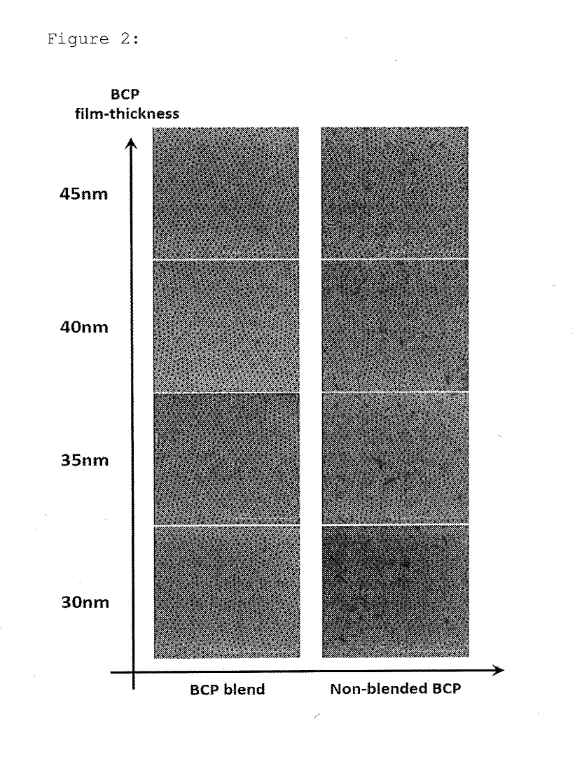

FIG. 2 exhibits SEM photos of blended composition (4 and 5) and non blended copolymer 3 for different thicknesses. It can be seen that blended composition exhibit less coordinance defectivity at higher thicknesses.

SEM pictures were obtained using scanning electron microscope “CD-SEM H9300” from Hitachi with a magnifying of 100 000. Each picture as a dimension of 1349×1349 nm.

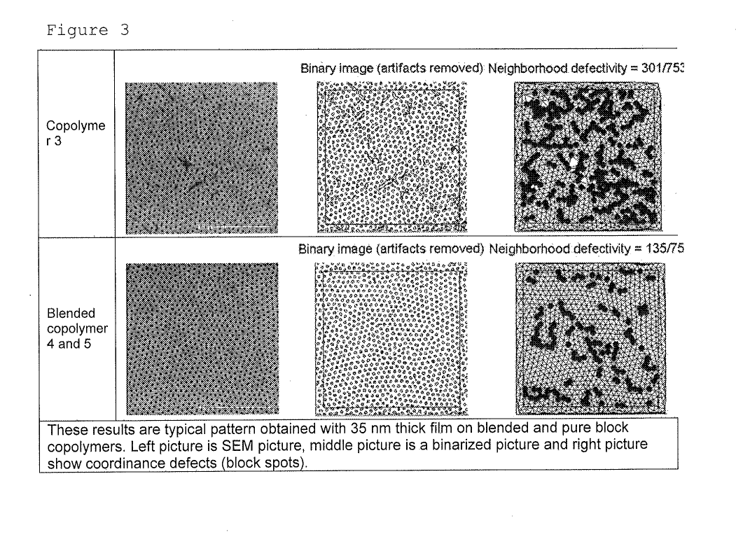

Numerical value on obtained with adequate known software were obtained and can be seen on table 4. A detail way of measuring coordinance defect is described for example in WO 2015032890 and FIG. 3 exhibit corresponding typical pattern.

TABLE 4

| | | | | | Coordi- |
|---|---|---|---|---|---|
| | Film | | Number of | Number of | nance |
| | thickness | period | cylinders | cylinders | defects |
| | (nm) | (nm) | detected | with defects | (%) |
| Copolymer 3 | 30 | 48.1 | 856 | 474 | 55.4 |
| | 35 | 48.1 | 753 | 301 | 40.0 |
| | 40 | 47.5 | 741 | 232 | 31.3 |
| | 45 | 46.6 | 732 | 215 | 29.4 |
| Blended | 30 | 48.4 | 740 | 163 | 22.0 |
| copolymer 4 | 35 | 47.1 | 750 | 135 | 18.0 |
| and 5 | 40 | 47.3 | 761 | 162 | 21.3 |
| | 45 | 47.8 | 732 | 145 | 19.8 |

1. A process for reducing the number of defects of an ordered film of block copolymer, said ordered film comprising a mixture of at least one block copolymer having an order-disorder transition temperature (TODT) and at least one Tg with at least one compound not having a TODT, wherein said compound is selected from the group consisting of block-copolymers, light or heat stabilizers, photo-initiators, polymeric ionic compounds, non-polymeric ionic compounds, homopolymers, and statistical copolymers, this mixture having a TODT below the TODT of the block copolymer alone, the process comprising the steps of:
mixing at least one block copolymer having a TODT and at least one compound not having a TODT, in a solvent to form a mixture;
depositing the mixture on a surface; and
curing the mixture deposited on the surface at a temperature between the highest Tg of the block copolymer and the TODT of the mixture.

2. The process according to claim 1, wherein the block copolymer having a TODT is a diblock copolymer.

3. The process according to claim 2, wherein one of the blocks of the diblock copolymer comprises a styrene monomer and the other block comprises a methacrylic monomer.

4. The process according to claim 3, wherein one of the blocks of the diblock copolymer comprises styrene and the other block comprises methyl methacrylate.

5. The process according to claim 1, wherein the block copolymer not having a TODT is a diblock copolymer.

6. The process according to claim 5, wherein one of the blocks of the diblock copolymer comprises a styrene monomer and the other block comprises a methacrylic monomer.

7. The process according to claim 6, wherein one of the blocks of the diblock copolymer comprises styrene and the other block comprises methyl methacrylate.

8. The process according to claim 1, wherein the surface is free.

9. The process according to claim 1, wherein the surface is guided.

10. A composition comprising at least one block copolymer having a TODT and at least one compound, wherein the one or more compounds do not have a TODT.

11. (canceled)

12. A lithography mask or ordered film prepared by the process of claim 1.
